(19) United States
(12) Patent Application Publication
(10) Pub. No.: US 2026/0130255 A1
(43) Pub. Date: May 7, 2026

(54) CHIP PACKAGING METHOD AND CHIP PACKAGING STRUCTURE

(71) Applicant: inSync Resonance Inc, Fremont, CA (US)

(72) Inventors: Sae Won LEE, Santa Clara, CA (US); Qin ZHOU, Fremont, CA (US)

(21) Appl. No.: 18/939,438

(22) Filed: Nov. 6, 2024

(51) Int. Cl. H01L 23/00

(52) U.S. Cl. CPC H10W 72/072; H10W 72/20; H10W 72/07202; H10W 72/07237; H10W 72/07252; H10W 72/221; H10W 72/285; H10W 90/724

(57) ABSTRACT

Provided are a chip packaging method and a chip packaging structure. The method includes: arranging a spacer on at least one of a first surface of a package substrate and a second surface of a chip; arranging a first adhesive on at least one of the first surface, the second surface, or the spacer; bringing together the package substrate and the chip, to sandwich the spacer between the first surface and the second surface, and adhere the first surface to the second surface by the first adhesive; and curing the first adhesive. With the chip packaging structure generated based on the above-mentioned method, a shear displacement of the first adhesive can be increased under a given load to reduce an attachment area of the chip, ensuring a height of the first adhesive.

### FIELD

The present disclosure relates to a packaging method, and more particularly, to a chip packaging method and a chip packaging structure.

### BACKGROUND

In a chip packaging method in the related technologies, an attachment material is generally used to directly cover whole or part of a chip region. When environmental factors change, such as a chip temperature is too high, a thermal expansion mismatch occurs between a chip and a package, and thus a lateral displacement of the chip with respect to the package occurs. Since a lateral load due to the thermal expansion mismatch cannot be easily released through a lateral displacement of the attachment material and most of the load causes the chip to bend, an optical surface of the chip is deformed. A deformation of the optical surface of the chip leads to an unsatisfying optical quality.

For example, for a vehicle, a micro-electro-mechanical system (MEMS) optical scanner is used in a LiDAR to create a real-time 3D map for the vehicle. In use, it is vital that the scanner's effect on the divergence of the light source is kept minimal, which requires the scanner surface to be as flat as possible. However, even with an optically flat MEMS optical scanner die, after packaging, the influence on the divergence can be substantial with conventional die attachment methods (i.e., the packaging process caused die surface deformation). If the MEMS optical scanner obtained through a conventional chip attachment method is designed improperly, temperature variation of the chip causes thermal expansions of both the chip and the package. However, degrees of expansion of both the chip and the package cannot be consistent, which results in stresses and deformations in the chip. Therefore, with the conventional chip attachment method, a beam quality is likely to be seriously affected due to the stresses and the deformations of the chip. In addition to optical MEMS, in many other MEMS devices as well as some semiconductor and integrated circuit devices, the chip is packaged through the conventional attachment method, which causes environment-induced problems such as stresses and deformations during use.

Therefore, there is some room for improvement in a packaging method for a chip packaged through attachment.

### SUMMARY

According to an embodiment in a first aspect of the present disclosure, a chip packaging method is provided. The chip packaging method includes: a step S1 of arranging a spacer on at least one of a first surface of a package substrate and a second surface of a chip, a step S2 of arranging a first adhesive on at least one of the first surface, the second surface, or the spacer, a step S3 of bringing together the first surface of the package substrate and the second surface of the chip, to sandwich the spacer between the first surface and the second surface, and adhere the first surface to the second surface by the first adhesive, or adhere the first surface to the second surface by the first adhesive and the spacer, a distribution area of the first adhesive at the second surface is smaller than an area of the second surface, and S4, curing the first adhesive.

According to an embodiment in a second aspect of the present disclosure, a chip packaging structure is provided. The chip packaging structure applies the above-mentioned chip packaging method and includes: a package substrate having a first surface. A chip having a second surface, a void layer being formed between the first surface and the second surface; a spacer sandwiched between the first surface and the second surface. The chip packaging structure further includes a first adhesive arranged in the void layer, the first surface being adhered to the second surface by the first adhesive, or the first surface and the second surface being adhered to the first adhesive by the spacer. A distribution area of the first adhesive at the second surface is smaller than an area of the second surface.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic view of an adhesive connection applied between a chip and a package substrate in the related art.

FIG. 2 is a flowchart illustrating a chip packaging method according to an embodiment of the present disclosure.

FIG. 3 is a schematic view of arranging a spacer at a first surface of a package substrate according to some embodiments of the present disclosure.

FIG. 4 is a schematic view of arranging a first adhesive at the first surface of the package substrate according to the embodiments illustrated in FIG. 3 after arranging the spacer at the first surface of the package substrate.

FIG. 5 is a schematic view of attaching a chip to the package substrate according to the embodiments illustrated in FIG. 4.

FIG. 6 is a schematic view of sequentially arranging a spacer and a first adhesive at a first surface of a package substrate according to some other embodiments of the present disclosure.

FIG. 7 is a schematic view of sequentially arranging a spacer and a first adhesive at a first surface of a package substrate according to yet some other embodiments of the present disclosure.

FIG. 8 is a flowchart illustrating a chip packaging method according to some embodiments of the present disclosure.

FIG. 9 is a schematic view showing a distribution of a spacer at a package substrate according to some embodiments of the present disclosure.

FIG. 10 is a schematic view showing a distribution of the spacer and a first adhesive at the package substrate based on an embodiment illustrated in FIG. 9.

FIG. 11 is a schematic view showing another distribution of the spacer and a first adhesive at the package substrate based on an embodiment illustrated in FIG. 9.

FIG. 12 is a schematic view showing a distribution of a spacer at a package substrate according to some other embodiments of the present disclosure.

FIG. 13 is a schematic view showing a distribution of the spacer and a first adhesive at the package substrate based on an embodiment illustrated in FIG. 12.

FIG. 14 is a schematic view showing another distribution of the spacer and a first adhesive at the package substrate based on an embodiment illustrated in FIG. 12.

Reference numerals of the accompanying drawings:

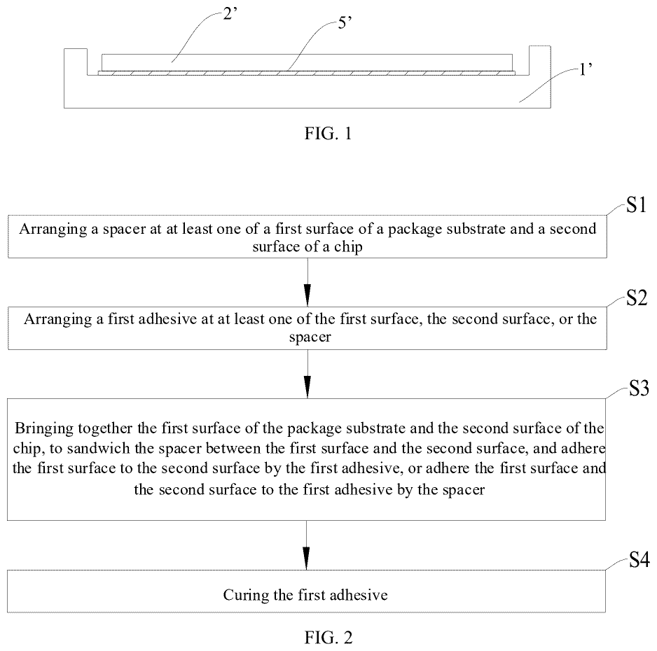

In FIG. 1: package substrate 1′; chip 2′; void layer 5′;

In the remaining figures: chip packaging structure 100; package substrate 1; first surface 10; chip 2; second surface 20; first adhesive 3; second adhesive 4; spacer 40; void layer 5.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

In the description of the present disclosure, it should be understood that, the orientation or the position indicated by terms such as “over,” “below,” “vertical,” “horizontal,” “top,” “bottom,” “inner,” and “outer” should be construed to refer to the orientation and the position as shown in the drawings, and is only for the convenience of describing the present disclosure and simplifying the description, rather than indicating or implying that the pointed device or element must have a specific orientation, or be constructed and operated in a specific orientation, and therefore cannot be understood as a limitation of the present disclosure. Further, the features associated with “first” and “second” may explicitly or implicitly include at least one of the features. In the description of the present disclosure, “plurality” means at least two, unless otherwise stated.

In the description of the present disclosure, it should be noted that, unless otherwise clearly stipulated and limited, terms such as “mount,” “connect,” “connect to” should be understood in a broad sense. For example, it may be a fixed connection or a detachable connection or connection as one piece; mechanical connection or electrical connection; direct connection or indirect connection through an intermediate; or internal communication of two components. For those skilled in the art, specific meanings of the above-mentioned terms in the present disclosure can be understood according to specific circumstances.

In the related art of chip packaging, one scheme of chip packaging is to coat a chip and a package substrate with an attachment material, and then cure the attachment material to enable that a relative position between the chip and the package substrate remains unchanged. In this way, the chip can be packaged and kept parallel.

Taking a MEMS optical scanner as an example, when the attachment material is attached to a chip in the MEMS optical scanner initially, the attachment material is adapted to the chip when the chip is not in use. An initial stress distribution of the chip matches with a bonding state. However, after the MEMS optical scanner is used, a temperature variation during normal operation of the MEMS optical scanner causes changes in the stress distribution of the chip, resulting in mismatch between the stress distribution and the bonding state. When this stress mismatch is large, divergence of the MEMS optical scanner can be affected. The MEMS is referred to as a micro-electro-mechanical system, also known as a micro-system, a micro-machine, etc.

The present disclosure aims to solve at least one of the technical problems in the related art. To this end, an object of the present disclosure is to provide a chip packaging method. A surface of a chip packaged through the chip packaging method can easily release environment-induced stresses, reducing a deformation degree of the chip after being heated.

Another object of the present disclosure is to provide a chip packaging structure obtained by using the above-mentioned chip packaging method.

With the chip packaging method according to the embodiments of the present disclosure, the spacer and the first adhesive are arranged in the void layer between the first surface of the package substrate and the second surface of the chip. After the void layer is supported by the spacer, the first surface and the second surface are adhered to each other by the first adhesive, maintaining flatness of the chip.

Since the spacer is provided to support the void layer, the void layer no longer needs to be filled with the first adhesive. Therefore, in the present disclosure, when the first adhesive is arranged, a distribution area of the first adhesive at the second surface is smaller than the area of the second surface. Considering that the void layer is supported by the spacer, a surface tension of the first adhesive and a weight of the chip (or the package substrate) is less likely to make the first adhesive too thin, in such a manner that a height of the first adhesive that is cured is guaranteed.

A chip packaging structure obtained through this method realizes low-stress attachment of the chip. When the chip is affected by an external environment or heat generated due to its own operation, a lateral displacement of the chip with respect to the package substrate occurs in response to a thermal expansion mismatch between the chip and the package substrate. Since an attachment area on the chip is reduced, a lateral constraint of the chip by the first adhesive is reduced. In addition, after the height of the first adhesive is guaranteed, an ability of the first adhesive to absorb a shear displacement through its own deformation is increased. Therefore, the chip can more easily release an expansion and internal stresses through the lateral displacement, to reduce a degree of deformation and a degree of warpage of the chip and to reduce stresses on the chip. Therefore, when the chip packaging structure constructs an optical surface through the chip, the chip packaging method according to solutions of the present disclosure enables the optical surface to be less likely to be deformed.

In particular, in some solutions, the first adhesive is made of a material that provides elasticity for the first adhesive that is cured. More particularly, the first adhesive is sufficiently soft when the first adhesive is sufficiently high. With the generated chip packaging structure, under a given load, the packaging method of the present disclosure can increase the shear displacement of the first adhesive and reduce an attachment area of the chip, guaranteeing the height of the first adhesive.

In the chip packaging method according to some embodiments of the present disclosure, the step S1 includes: a step S11 of arranging a second adhesive on at least one of the first surface of the package substrate and the second surface of the chip, and a step S12 of curing the second adhesive, the spacer being formed by the second adhesive that is cured.

In some embodiments, the second adhesive is made of a same material as the first adhesive.

In the chip packaging method according to some embodiments of the present disclosure, in the step S11 of arranging the second adhesive, a plurality of second adhesives in equal amounts are arranged at a plurality of positions on at least one of the first surface and the second surface, the plurality of positions being separated from each other.

In another exemplary embodiment of the present disclosure, in the step S12 of curing the second adhesive, the first surface or the second surface on which the second adhesive is arranged is kept horizontally stationary, allowing a plurality of spacers formed by curing the plurality of second adhesives at the plurality of positions on the at least one of the first surface and the second surface to be of equal height and having each a smooth arc top surface.

In some embodiments, during the arranging the first adhesive in step S2, a plurality of first adhesives in equal amounts are arranged at a plurality of positions on at least one of the first surface and the second surface, and the plurality of positions being separated from each other. The plurality of first adhesives and a plurality of spacers are arranged at intervals when the first surface and the second surface are brought together, and an amount of a corresponding one first adhesive of the plurality of first adhesives arranged at each of the plurality of position on the at least one of the first surface and the second surface is greater than or equal to an amount of a corresponding one second adhesive of the plurality of second adhesives arranged at each of the plurality of positions on the at least one of the first surface and the second surface in step S12.

In some embodiments, during the arranging the first adhesive in the step S2, at least part of the first adhesive is arranged on the spacer.

In some embodiments, the step S12 includes: curing the second adhesive for a first time, and detecting whether the cured second adhesive reaches a predetermined height, and in response to that the cured second adhesive fails to reach the predetermined height, replenishing the second adhesive, and performing said curing and said detection again, until the cured second adhesive reaches the predetermined height.

In some embodiments, in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

According to the embodiments of the present disclosure, the chip packaging structure obtained through applying the above-mentioned chip packaging method realizes low-stress attachment of the chip. When the chip is affected by the external environment or the heat generated due to its own operation, the lateral displacement of the chip with respect to the package substrate occurs in response to the thermal expansion mismatch between the chip and the package substrate. Since the attachment area on the chip is reduced, the lateral constraint of the chip by the first adhesive is reduced. In addition, after the height of the first adhesive is guaranteed, the ability of the first adhesive to absorb the shear displacement through its own deformation is increased. Therefore, the chip can more easily release the expansion and the internal stresses through the lateral displacement, to reduce the degree of deformation and the degree of warpage of the chip and to reduce the stresses on the chip. Therefore, when the chip packaging structure constructs the optical surface through the chip, the optical surface is less likely to be deformed.

Additional aspects and advantages of the present disclosure will be provided at least in part in the following description, or will become apparent at least in part from the following description, or can be learned from practicing of the present disclosure.

In some typical packaging schemes, as illustrated in FIG. 1, when the attachment material is attached to a chip 2′, the attachment material should be applied to the entire chip. That is, a void layer 5′ between the chip 2′ and a package substrate 1′ is filled with the attachment material.

When a thermal expansion mismatch exists between the chip 2′ and the package substrate 1′, a lateral displacement of the chip 2′ with respect to the package substrate 1′ occurs. A lateral load that occurs due to the thermal expansion mismatch cannot be easily released by the lateral displacement of the attachment material and most of the load causes flexure on the chip 2′, leading to a deformation of an optical surface. If the attachment material allows for a large shear displacement under a fairly low load, not much stress due to the thermal expansion mismatch is left, and the deformation of the optical surface can be minimized.

To solve the above problems, a chip packaging method is provided by the present disclosure. The chip packaging method according to an embodiment in a first aspect of the present disclosure is described below with reference to FIG. 2 to FIG. 14.

As illustrated in FIG. 2, the chip packaging method according to an embodiment of the present disclosure includes: a step S1 of arranging a spacer 40 on at least one of a first surface 10 of a package substrate 1 and a second surface 20 of a chip 2, a step S2 of arranging a first adhesive 3 on at least one of the first surface 10, the second surface 20, or the spacer 40, a step S3 of bringing together the first surface 10 of the package substrate 1 and the second surface 20 of the chip 2, to sandwich the spacer 40 between the first surface 10 and the second surface 20, and adhere the first surface 10 to the second surface 20 by the first adhesive 3, or adhere the first surface 10 to the second surface 20 by the first adhesive 3 and the spacer 40, a distribution area of the first adhesive 3 at the second surface 20 is smaller than an area of the second surface 20, and a step of S4 of curing the first adhesive 3.

In the step S1, the spacer 40 may be selectively arranged only at the first surface 10 of the package substrate 1 or may be selectively arranged only at the second surface 20 of the chip 2. Or, in some solutions, each of the first surface 10 of the package substrate 1 and the second surface 20 of the chip 2 is provided with the spacer 40. In these solutions, it should be noted that in the step S3 of bringing together the first surface 10 of the package substrate 1 and the second surface 20 of the chip 2, the spacer 40 at the first surface 10 and the spacer 40 at the second surface 20 need to be offset from each other, in such a manner that the spacers 40 are prevented from being stacked on each other in a thickness direction of the chip 2.

In the step S2, the first adhesive 3 may be selectively arranged only at the first surface 10 of the package substrate 1 or may be selectively arranged only at the second surface 20 of the chip 2. Or, in some solutions, each of the first surface 10 of the package substrate 1 and the second surface 20 of the chip 2 is provided with the first adhesive 3.

Or, according to some embodiments, in the step S2, at least part of the first adhesive 3 is arranged on the spacer 40. As an example, the first adhesive 3 is arranged in an adhesive-dispensing manner. The adhesive may only be arranged on the spacer 40. When dispensed in a small amount, the first adhesive 3 remains stationary at the spacer 40 without flowing, in such a manner that the first adhesive 3 is stuck to neither the first surface 10 nor the second surface 20 at which the spacer 40 is arranged. Or, when dispensed in a large amount, the first adhesive 3 partly remains stationary at the spacer 40, and partly flows and sticks to the first surface 10 or the second surface 20 at which the spacer 40 is arranged. Or, during dispensing of the first adhesive 3, part of the first adhesive 3 is dispensed directly at the spacer 40, and part of the first adhesive 3 is dispensed directly on at least one of the first surface 10 and the second surface 20.

It should be noted that in some solutions, the spacer 40 and the first adhesive 3 are arranged without interfering with each other. The step S1 can be performed before or after the step S2, or the step S1 and the step S2 can be performed simultaneously, as long as the step S3 is not affected.

In the step S3, an operation manner of bringing together the first surface 10 of the package substrate 1 and the second surface 20 of the chip 2 is not limited. The package substrate 1 may be kept stationary. The first surface 10 may be kept upwards and horizontal. Then, the chip 2 is taken with a claw, a suction cup, or the like, to place the second surface 20 of the chip 2 face down at the package substrate 1. Or, the chip 2 may be kept stationary. The second surface 20 may be kept upwards and horizontal. Then, the package substrate 1 is taken with a claw, a suction cup, or the like, to place the first surface 10 of the package substrate 1 face down at the chip 2. Or, in some solutions, the package substrate 1 and the chip 2 are taken with a claw and a suction cup, respectively. The package substrate 1 and the chip 2 are brought together in a vertical state.

In the step S3, after the first surface 10 of the package substrate 1 and the second surface 20 of the chip 2 are brought together, a void layer 5 is formed between the package substrate 1 and the chip 2 through support of the spacer 40. With the spacer 40, the chip 2 is maintained at a predetermined distance from the package substrate 1. The predetermined distance is a height of the spacer 40, also known as a thickness of the void layer 5. The height of the spacer 40 refers to a size of the spacer 40 in the thickness direction of the chip 2.

Support provided by the spacer 40 can protect the chip 2 from being bent and deformed by a tension of the first adhesive 3 during a curing process of the first adhesive 3, which is conducive to improving flatness of a surface of the chip 2. In addition, a height of the first adhesive 3 that is cured can be therefore fixed and maintained. A resultant stress is gradually released through the support of the spacer 40. The first adhesive 3 that is cured is adapted to a chip environment. The height of the first adhesive 3 is consistent with the height of the spacer 40. The height of the spacer 40 can be adjusted as desired to ensure sufficient interlayer gaps between the chip 2 and the package substrate 1.

In addition, the spacer 40 can provide sufficient friction to the chip 2 or the package substrate 1 in the step S3, in such a manner that an alignment of the chip 2 is less likely to be affected during the curing of the first adhesive 3.

In the step S3, after the first surface 10 of the package substrate 1 and the second surface 20 of the chip 2 are brought together, the first adhesive 3 may directly adhere to both the first surface 10 and the second surface 20 in some solutions. Or, in some other solutions, the first adhesive 3 may directly adhere to one of the first surface 10 and the second surface 20, and indirectly adhere to the other one of the first surface 10 and the second surface 20 by the spacer 40. In this way, after the step S4 of curing the first adhesive 3, the package substrate 1 and the chip 2 are integrally fixed, maintaining a stable relative position between the chip 2 and the package substrate 1.

After the first surface 10 of the package substrate 1 and the second surface 20 of the chip 2 are brought together, the package substrate 1 and the chip 2 may be let stand, or the package substrate 1 and the chip 2 may be pressed against each other by an external object. When cured, the first adhesive 3 may be let stand or placed in an environment where the curing can be accelerated. In particular, in some embodiments, in the step S4, the package substrate 1 and the chip 2 may be tightly pressed against each other. The first surface 10 and the second surface 20 are kept parallel to each other during tightly pressing the package substrate 1 and the chip 2 against each other. In addition, the spacer 40 is in contact with the first surface 10 and the second surface 20. With such an arrangement, the void layer 5 has the thickness that can be guaranteed to be equal to the height of the spacer 40, thereby reducing occurrences of skew of the first surface 10 and the second surface 20 caused by local tension and stress. A way in which the package substrate 1 and the chip 2 are tightly pressed against each other and kept parallel to each other can be performed using a scheme known in the related art.

In another exemplary embodiment of the present disclosure, the first adhesive 3 is a UV adhesive. In the step S4, the UV adhesive is irradiated with UV light. In some solutions, the first adhesive 3 is baked or the like in step S4. Baking of the first adhesive 3 can be tailored as desired to achieve a desired initial attachment stress of the chip 2, widening or changing an optimal operation range.

With the chip packaging method according to the embodiments of the present disclosure, the spacer 40 and the first adhesive 3 are arranged in the void layer 5 between the first surface 10 of the package substrate 1 and the second surface 20 of the chip 2. After the void layer 5 is supported by the spacer 40, the first surface 10 and the second surface 20 are adhered to each other by the first adhesive 3, maintaining flatness of the chip 2.

Since the spacer 40 is provided to support the void layer 5, the void layer 5 no longer needs to be filled with the first adhesive 3. Therefore, in the present disclosure, when the first adhesive 3 is arranged, a distribution area of the first adhesive 3 at the second surface 20 is smaller than the area of the second surface 20. Considering that the void layer 5 is supported by the spacer 40, a surface tension of the first adhesive 3 and a weight of the chip 2 (or the package substrate 1) is less likely to make the first adhesive 3 too thin, in such a manner that the height of the first adhesive 3 that is cured is guaranteed. In other embodiments of the present disclosure, the spacer 40 here should be high enough to meet attachment thickness requirements of the chip 2, while allowing the first adhesive 3 to be in contact with the chip 2 and the package substrate 1 at an attachment position.

A chip packaging structure 100 obtained through this method realizes low-stress attachment of the chip 2. When the chip 2 is affected by an external environment or heat generated due to its own operation, a lateral displacement of the chip 2 with respect to the package substrate 1 occurs in response to the thermal expansion mismatch between the chip 2 and the package substrate 1. Since an attachment area on the chip 2 is reduced, a lateral constraint of the chip 2 by the first adhesive 3 is reduced. In addition, after the height of the first adhesive 3 is guaranteed, an ability of the first adhesive 3 to absorb a shear displacement through its own deformation is increased. Therefore, the chip 2 can more easily release an expansion and internal stresses through the lateral displacement, to reduce a degree of deformation and a degree of warpage of the chip 2 and to reduce stresses on the chip 2. Therefore, when the chip packaging structure 100 constructs an optical surface through the chip 2, the chip packaging method according to the solutions of the present disclosure enables the optical surface to be less likely to be deformed.

In particular, in some solutions, the first adhesive 3 is made of a material that provides elasticity for the first adhesive 3 that is cured. More particularly, the first adhesive 3 is sufficiently soft when the first adhesive 3 is sufficiently high. With the generated chip packaging structure 100, under a given load, the packaging method of the present disclosure can increase the shear displacement of the first adhesive 3 and reduce an attachment area of the chip 2, guaranteeing the height of the first adhesive 3. The shear displacement of the first adhesive 3 can be maximized even under the given load of the chip package structure 100. The first adhesive 3 can absorb all the thermal expansion mismatch between the chip 2 and the package substrate 1.

When the chip packaging method in the present disclosure is applied in an attachment scene of the chip 2 of the MEMS optical scanner, a minimal change in optical divergence is measured during operation with temperature variations between −40° C. and 105° C. A shock test of up to 2,000 G has been passed with the MEMS optical scanner, showing a dampening property of the packaged chip 2.

In the solutions according to the present disclosure, since the first adhesive 3 has a limited distribution range, an amount of the adhesive can be better controlled to guarantee that the first adhesive 3 can be concentrated in a key region, while ensuring that key parts of the interlayer gaps are filled with sufficient adhesive and that adhesion is enhanced. In this way, unnecessary waste or excessive filling can be avoided. By precisely controlling the distribution of the first adhesive 3, an interaction between the adhesive and a surface connected to the adhesive can be optimized, which improves an adhesion effect and stability of the packaging structure.

In addition, such a distribution also helps to reduce an influence of the first adhesive 3 on surrounding components. Since the first adhesive 3 has a reduced distribution area, the first adhesive 3 is less likely to flow to a surrounding region, which helps to improve reliability and consistency of the chip packaging structure 100, mitigating potential side effects or adverse effects.

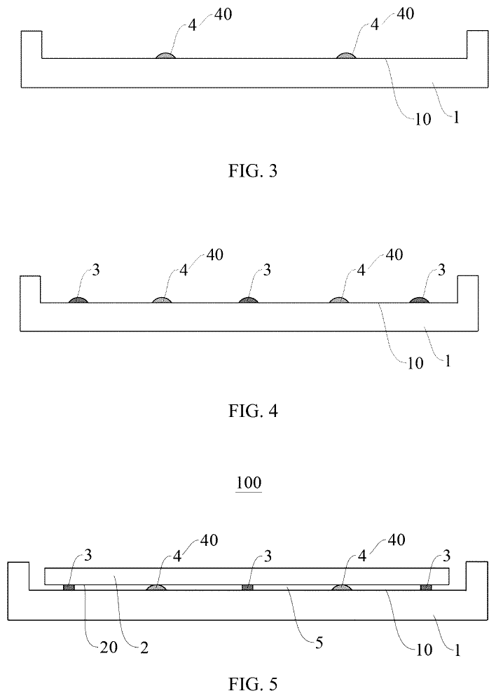

FIG. 3 to FIG. 5 illustrate a chip packaging process according to some specific embodiments.

As illustrated in FIG. 3, in the step S1, the spacer 40 is arranged at the first surface 10 of the package substrate 1. In FIG. 3, the spacers 40 are arranged on at least two parts of the first surface 10.

As illustrated in FIG. 4, in the step S2, the first adhesive 3 is arranged at the first surface 10 of the package substrate 1. In FIG. 4, the first adhesives 3 are arranged on at least three parts of the first surface 10.

As illustrated in FIG. 5, in the step S5, the first surface 10 of the package substrate 1 and the second surface 20 of the chip 2 are brought together. In this case, the chip 2 is supported by the spacer 40 to adhere the first adhesive 3 to the first surface 10 of the package substrate 1 and the second surface 20 of the chip 2. Then, the first adhesive 3 is left to stand for curing.

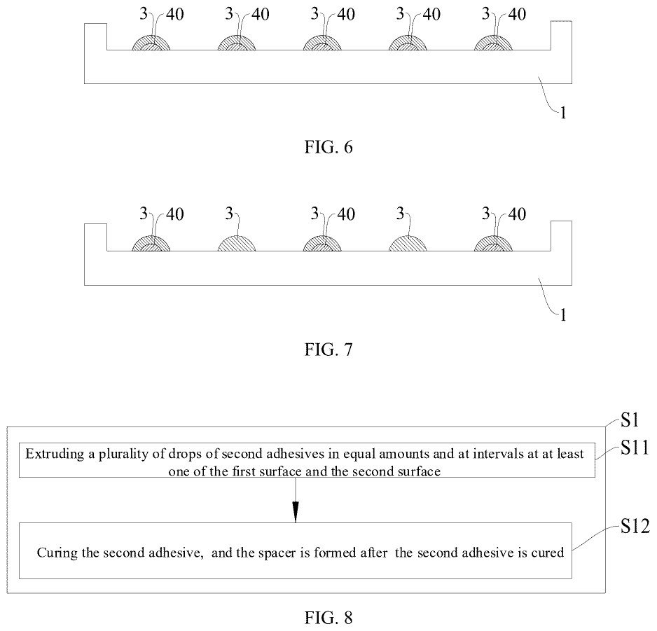

FIG. 6 illustrates an implementation of step S2 according to some other specific embodiments. That is, after the spacer 40 is arranged at the first surface 10 of the package substrate 1, all the first adhesives 3 are arranged on the spacer 40 while arranging the first adhesives 3 at the first surface 10 of the package substrate 1.

FIG. 7 illustrates an implementation of step S2 according to yet some other specific embodiments. That is, after the spacer 40 is arranged at the first surface 10 of the package substrate 1, part of the first adhesives 3 are arranged on the spacer 40, and part of the first adhesives 3 are directly arranged at the first surface 10 and separated from the spacer 40, while arranging the first adhesives 3 at the first surface 10 of the package substrate 1.

The first surface 10 and the second surface 20 are separated by the spacer 40. Maintaining a fixed connection between the first surface 10 and the second surface 20 by the first adhesive 3 ensures stable adhesion between the first surface 10 and the second surface 20. Therefore, the interlayer gaps between the first surface 10 and the second surface 20 are kept uniform. An adhesive force and elasticity of the first adhesive 3 can make the first adhesive 3 maintain a relatively stable state even in the face of external impact or vibration. In this way, a damage-resistant capability of the chip 2 can be greatly enhanced, which improves the reliability of the entire chip packaging structure 100.

More specific embodiments can be obtained through combinations depending on selections of positions of the first adhesive 3 and the spacer 40. Details thereof will be omitted here.

As illustrated in FIG. 8, according to some embodiments of the present disclosure, a process of arranging the spacer 40 in step S1 may be further broken down into: a step of S11 of arranging a second adhesive 4 on at least one of the first surface 10 of the package substrate 1 and the second surface 20 of the chip 2, and a step of S12 of curing the second adhesive 4, the spacer 40 being formed by the second adhesive 4 that is cured.

In the step S11, the second adhesive 4 may be selectively arranged only at the first surface 10 of the package substrate 1 or may be selectively arranged only at the second surface 20 of the chip 2. Or, in some solutions, each of the first surface 10 of the package substrate 1 and the second surface 20 of the chip 2 is provided with the second adhesive 4. In these solutions, it should be noted that in the step S3 of bringing together the first surface 10 of the package substrate 1 and the second surface 20 of the chip 2, the second adhesives 4 at the first surface 10 and the second surface 20 need to be offset from each other, in such a manner that the spacers 40 that are cured are prevented from being stacked on each other in the thickness direction of the chip 2.

In this way, the second adhesive 4 is transformed into the spacer 40 having a predetermined degree of hardness. The spacer 40 is in a specific shape. The spacer 40 can provide sufficient support strength. Further, the spacer 40 has a top end providing a sufficient coefficient of friction. This support strength ensures that the chip 2 can be stably maintained in a predetermined position without being displaced due to external forces or a weight of the chip 2.

Arranging the spacer 40 using the second adhesive 4 allows a position of the spacer 40 to be pre-fixed. As an example, the second adhesive 4 is arranged at the first surface 10 of the package substrate 1 in the step S11. The second adhesive 4 that is cured is adhered to the first surface 10. In this way, when the chip 2 is subsequently attached to the package substrate 1, the second adhesive 4 can stably support the chip 2 after the alignment of the chip 2, considering that the second adhesive 4 can tightly adhere to the package substrate 1. A friction between the spacer 40 and the chip 2 can prevent the chip 2 from moving easily.

In some specific embodiments, the second adhesive 4 is made of a same material as the first adhesive 3. Using the same material means that purchase of different materials can be reduced during manufacturing, simplifying supply chain management. The same material helps to maintain process consistency, improving a manufacturing efficiency. With the same material, support forces from the spacer 40 and the first adhesive 3 that is cured at the chip 2 are substantially the same, which is conducive to improving force balance of the chip 2 and reducing a local concentrated stress on the chip 2.

When the chip packaging method in the present disclosure is implemented, the use of the same material for the first adhesive 3 and the second adhesive 4 can further ensure that the first adhesive 3 and the second adhesive 4 have consistent physical and chemical properties, helping to achieve an accurate and reliable packaging effect.

In other embodiments of the present disclosure, the solutions of the present disclosure do not exclude that the first adhesive 3 and the second adhesive 4 are made of different materials.

In some exemplary embodiment of the present disclosure, the first adhesive 3 is silica gel. Since the silica gel can be formulated to have a low tensile modulus, the first adhesive 3 is made relatively soft. Further, the first adhesive 3 absorbs the shear displacement more easily through its own deformation. Another advantage of using the silica gel is that mechanical properties of the chip 2 do not change significantly within temperatures exposed to applications. The first adhesive 3 is kept from becoming brittle at a low temperature.

In another exemplary embodiment of the present disclosure, the first adhesive 3 may be a silicone member having characteristics of both an organic material and an inorganic material, and can therefore exhibit characteristics such as heat resistance, weather resistance, mechanical strength, inflammability, and electrical insulation.

Temperature resistance of the silicone member provides the first adhesive 3 with relatively high thermal stability and heat resistance, which can make the first adhesive 3 maintain good performance at a high temperature.

Chemical stability of the silicone member makes the first adhesive 3 less likely to chemically react with other substances, and thus the first adhesive 3 has satisfactory chemical stability, which means that the silica gel is unlikely to deteriorate during use. Therefore, performance of the silica gel can be maintained for a long time.

In other embodiments of the present disclosure, it is not excluded in the present disclosure that the first adhesive 3 may be made of other adhesive materials, such as epoxy resin. Neither the epoxy resin nor the silica gel is conductive. Based on needs of some application scenarios, the first adhesive 3 may also be made of conductive adhesive materials disclosed in the related art.

In some embodiments, the second adhesive 4 is silica gel. The spacer 40 formed by the second adhesive 4 that is cured also has satisfactory adsorption performance, temperature resistance, and chemical stability, ensuring that the packaged chip 2 has advantages such as stability and satisfactory heat resistance.

In other embodiments of the present disclosure, it is not excluded in the present disclosure that the second adhesive 4 may be made of other adhesive materials, such as epoxy resin. Neither the epoxy resin nor the silica gel is conductive. Based on needs of some application scenarios, the second adhesive 4 may also be made of conductive adhesive materials disclosed in the related art.

In another exemplary embodiment of the present disclosure, a raw material of glass may further be used as the second adhesive 4, in such a manner that the raw material of glass is operated in different temperature environments at different steps. In this way, after the raw material of glass is cured into the spacer 40, the spacer 40 becomes a glass body, which can support the interlayer gaps between the chip 2 and the package substrate 1.

Using the raw material of glass to obtain the spacer 40 ensures that the required adhesion force can be provided under high-temperature conditions, reliable support can be provided after cold solidification at a low temperature, and stability of the spacer 40 can be maintained during long-term use.

With the chip packaging method according to some embodiments, in the step S11 of arranging the second adhesive 4, a plurality of second adhesives 4 in equal amounts are arranged at a plurality of positions on at least one of the first surface 10 and the second surface 20. The plurality of positions on the at least one of the first surface 10 and the second surface 20 are separated from each other. Arranging the plurality of second adhesives 4 at intervals avoids adhesion between second adhesives 4 arranged at two adjacent parts, and thus the second adhesives 4 arranged at the two adjacent parts are unlikely to be in contact with each other due to viscosity and a surface tension of the adhesives, which is conducive to accurately controlling the heights of the spacers 40 formed after the second adhesives 4 are cured. By arranging the second adhesives 4 in equal amounts at the plurality of positions on the at least one of the first surface 10 and the second surface 20, the second adhesives 4 that are cured tend to have consistent shapes and heights based on material properties of the second adhesive 4, further accurately controlling the heights of the spacers 40 formed after the second adhesives 4 are cured.

In an exemplary embodiment of the present disclosure, when arranging the second adhesive 4, the second adhesives 4 are guaranteed to be formed in a uniform manner at respective parts and are uniformly distributed, which helps to ensure that the plurality of formed spacers 40 are of uniform shapes.

A way of arranging the second adhesives 4 in equal amounts also helps to control an amount of the second adhesives 4 as a whole, avoiding waste or shortage of the second adhesive 4.

Further, in the step S12 of curing the second adhesive 4 in step S12, the first surface 10 or the second surface 20 on which the second adhesive 4 is arranged is kept horizontally stationary, allowing a plurality of spacers formed by curing the plurality of second adhesives at the plurality of positions on the at least one of the first surface and the second surface to be of equal height and having each a smooth arc top surface. The smooth surface can mitigate stress concentration and increase a force-receiving area of the chip 2.

Height consistency of the second adhesives 4 at the plurality of parts can ensure a uniform and consistent spacing between the chip 2 and the package substrate 1, which is advantageous to keep the chip 2 flat after the first adhesive 3 is cured, improving the flatness of the chip 2, and reducing stresses or distortions caused by a height difference.

In some embodiments, the step S12 may be further broken down into: curing the second adhesive 4 for a first time; and detecting whether the cured second adhesive 4 reaches a predetermined height, and in response to that the cured second adhesive 4 fails to reach the predetermined height, replenishing the second adhesive 4, and performing said curing and said detection again, until the cured second adhesive 4 reaches the predetermined height.

In this way, with detection feedback, height consistency of the plurality of spacers 40 can be further ensured, which can improve support stability.

In some specific embodiments, in the step S2 of arranging the first adhesive 3, a plurality of first adhesives 3 in equal amounts are arranged at a plurality of positions on at least one of the first surface 10 and the second surface 20. The plurality of positions is separated from each other. An amount of a corresponding one first adhesive 3 of the plurality of first adhesives 3 arranged at each of the plurality of position on the at least one of the first surface 10 and the second surface 20 is greater than or equal to an amount of a corresponding one second adhesive of the plurality of second adhesives 4 arranged at each of the plurality of positions on the at least one of the first surface 10 and the second surface 20 in step S12. The plurality of first adhesives 3 and a plurality of spacers 40 are arranged at intervals when the first surface 10 and the second surface 20 are brought together. Such an arrangement is to ensure that after the second adhesive 4 is cured to form the spacer 40, the first adhesive 3 can be fully in contact with both the first surface 10 and the second surface 20, avoiding missed adhesion.

Since the first adhesive 3 is dispensed in a large amount, the interlayer gaps between the first surface 10 and the second surface 20 can be filled with the first adhesive 3 more satisfyingly. A continuous contact layer is formed after the first adhesives 3 are cured. The contact layer can enhance the adhesion force between the first surface 10 and the second surface 20, and ensure that the first surface 10 and the second surface 20 can be firmly attached to each other during subsequent packaging, improving reliability and high durability of packaging of the chip 2.

In some other specific embodiments, during arranging the first adhesive 3 in the step S2, the plurality of first adhesives 3 in equal amounts are arranged at the plurality of spacers 40. When the spacer 40 is formed by the second adhesive 4 that is cured, an amount of the first adhesive 3 and an amount of the second adhesive 4 are not limited at each part.

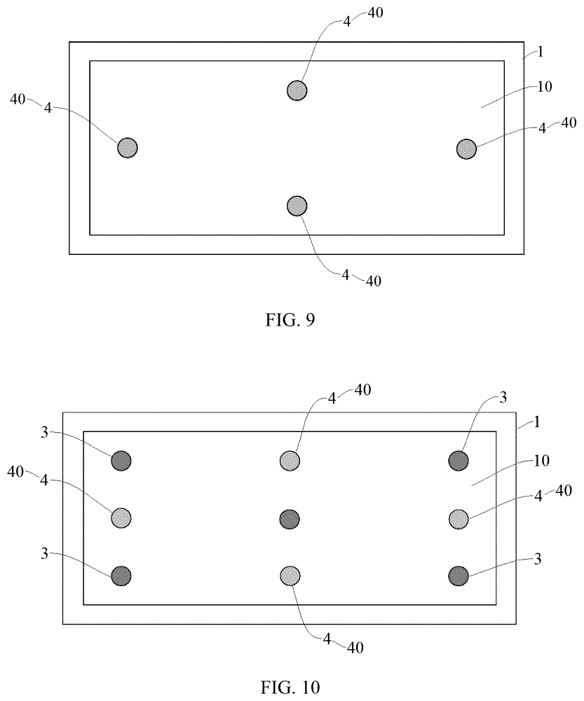

In some embodiments, as illustrated in FIG. 9 to FIG. 14, the first adhesive 3 is spaced apart from the spacer 40, which can prevent the spacer 40 from becoming high after the first adhesive 3 adheres to the spacer 40. The first adhesive 3, along with the spacer 40, realizes adhesion to more parts of the first surface 10 and the second surface 20, ensuring adhesion strength and reliability.

In the solutions of the present disclosure, the spacers 40 are distributed in a form of dots or lines. The first adhesives 3 are distributed in a form of dots, lines, or planes.

For example, in the chip packaging structure 100, the spacer 40 is linear and in a form of a single line. The spacer 40 may be distributed along an edge of the chip 2 or distributed in a form of a spiral line. Or, a plurality of spacers 40 are provided and arranged in a form of a plurality of lines. Or, a plurality of spacers 40 are provided and distributed in a form of dots. Or, the spacers 40 are partly distributed in the form of dots and partly distributed in the form of lines.

For example, in the chip packaging structure 100, the first adhesive 3 is linear and in a form of a single line. The first adhesive 3 may be distributed along an edge of the chip 2 or distributed in a form of a spiral line. Or, a plurality of first adhesives 3 are provided and arranged in a form of a plurality of lines. Or, a plurality of first adhesives 3 are provided and distributed in a form of dots. Or, the first adhesives 3 are partly distributed in the form of dots and partly distributed in the form of lines.

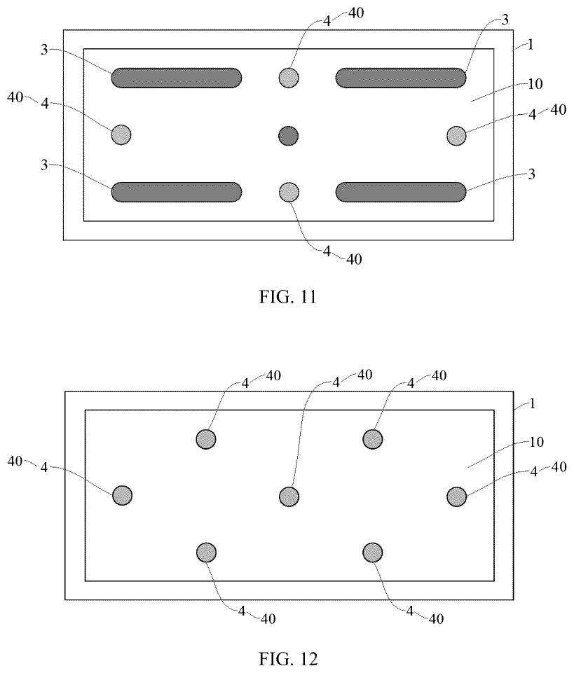

When the spacers 40 of a plurality of shapes and the first adhesives 3 of a plurality of shapes are combined, a plurality of setting shapes can be obtained. For example, as illustrated in FIG. 9, the spacers 40 at the package substrate 1 are distributed in a form of four dots. In this case, the first adhesives 3 may be distributed in a form of a plurality of dots as illustrated in FIG. 10, or the first adhesives 3 may be distributed in a form of a combination of a plurality of lines and a plurality of dots as illustrated in FIG. 11, but patterns formed in the two ways are different. In the examples illustrated in FIG. 10 and FIG. 11, the first adhesives 3 are coated at parts away from the spacers 40. In other examples, the first adhesives 3 are partly coated at parts away from the spacers 40 and partly coated on the spacers 40 illustrated in FIG. 10 and FIG. 11, or the first adhesive 3 may even cover the spacer 40.

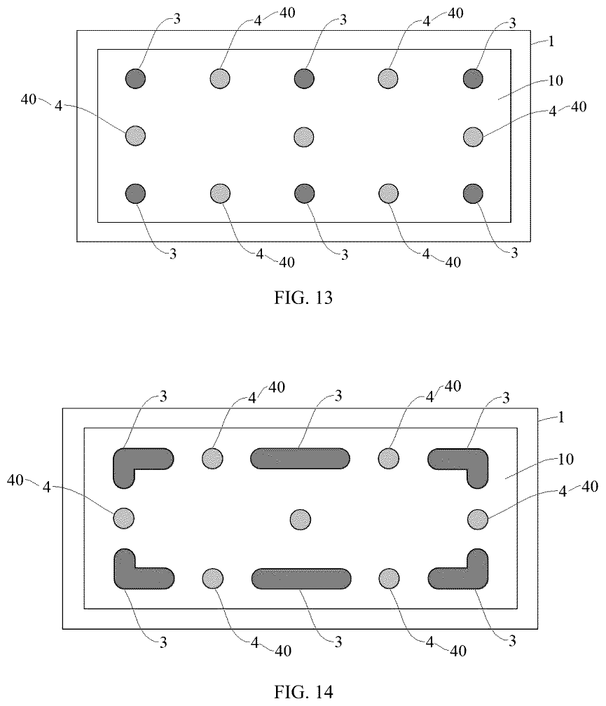

Further, as illustrated in FIG. 12, the spacers 40 at the package substrate 1 are distributed in a form of a plurality of dots. In this case, the first adhesives 3 may be distributed in a form of a plurality of dots as illustrated in FIG. 13 or in a form of a plurality of lines as illustrated in FIG. 14, optimizing shock resistance and vibration resistance. In the examples illustrated in FIG. 13 and FIG. 14, the first adhesives 3 are coated at parts away from the spacers 40. In other examples, the first adhesives 3 are partly coated at parts away from the spacers 40 and partly coated on the spacers 40 illustrated in FIG. 13 and FIG. 14, or the first adhesive 3 may even cover the spacer 40.

In a second aspect, a chip packaging structure 100 is provided according to the embodiments of the present disclosure. The chip packaging method mentioned above is applied to the chip packaging structure 100. As illustrated in FIG. 5, the chip packaging structure 100 includes a package substrate 1, a chip 2, a spacer 40, and a first adhesive 3. The package substrate 1 has a first surface 10. The chip 2 has a second surface 20. A void layer 5 is formed between the first surface 10 and the second surface 20. The spacer 40 and the first adhesive 3 are arranged in the void layer 5. The spacer 40 is sandwiched between the first surface 10 and the second surface 20. The first surface 10 is adhered to the second surface 20 by the first adhesive 3, or the first surface 10 and the second surface 2 is adhered to the first adhesive 3 by the spacer 40. A distribution area of the first adhesive 3 at the second surface 20 is smaller than an area of the second surface 20.

The chip packaging structure 100 obtained through this method realizes low-stress attachment of the chip 2. When the chip 2 is affected by an external environment or heat generated due to its own operation, a lateral displacement of the chip 2 with respect to the package substrate 1 occurs in response to the thermal expansion mismatch between the chip 2 and the package substrate 1. Since an attachment area on the chip 2 is reduced, a lateral constraint of the chip 2 by the first adhesive 3 is reduced. In addition, after the height of the first adhesive 3 is guaranteed, an ability of the first adhesive 3 to absorb a shear displacement through its own deformation is increased. Therefore, the chip 2 can more easily release an expansion and internal stresses through the lateral displacement, to reduce a degree of deformation and a degree of warpage of the chip 2 and to reduce stresses on the chip 2. Therefore, when the chip packaging structure 100 constructs an optical surface through the chip 2, the optical surface is less likely to be deformed.

Detailed structures of the chip packaging structure 100 are described in the above-mentioned method embodiments and will not be repeated herein. Reference throughout this specification to terms such as “an embodiment” and “an example” means that a particular feature, structure, material, or characteristic described in connection with the embodiment or example is included in at least one embodiment or example of the present disclosure. The appearances of the above phrases in various places throughout this specification are not necessarily referring to the same embodiment or example. Further, the particular features, structures, materials, or characteristics may be combined in any suitable manner in one or more embodiments or examples.

Although embodiments of the present disclosure have been illustrated and described, it is conceivable for those skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A chip packaging method, comprising:
a step S1 of arranging a spacer on at least one of a first surface of a package substrate and a second surface of a chip;
a step S2 of arranging a first adhesive on at least one of the first surface, the second surface, or the spacer;
a step S3 of bringing together the first surface of the package substrate and the second surface of the chip, to sandwich the spacer between the first surface and the second surface; and to adhere the first surface to the second surface by the first adhesive, or adhere the first surface to the second surface by the spacer and the first adhesive, wherein a distribution area of the first adhesive at the second surface is smaller than an area of the second surface; and
a step S4 of curing the first adhesive.

2. The chip packaging method according to claim 1, wherein the step S1 comprises:
a step S11 of arranging a second adhesive on at least one of the first surface of the package substrate and the second surface of the chip; and
a step S12 of curing the second adhesive, the spacer being formed by the cured second adhesive.

3. The chip packaging method according to claim 2, wherein the second adhesive is made of a same material as the first adhesive.

4. The chip packaging method according to claim 2, wherein in the step S11 of arranging the second adhesive, a plurality of second adhesives in equal amounts are arranged at a plurality of positions on at least one of the first surface and the second surface, the plurality of positions being separated from each other.

5. The chip packaging method according to claim 4, wherein in the step S12 of curing the second adhesive, the first surface or the second surface on which the plurality of second adhesives are arranged is kept horizontally stationary, allowing a plurality of spacers formed by curing the plurality of second adhesives at the plurality of positions on the at least one of the first surface and the second surface to be of equal height and having each a smooth arc top surface.

6. The chip packaging method according to claim 4, wherein:
in the step S2 of arranging the first adhesive, a plurality of first adhesives in equal amounts are arranged at a plurality of positions on at least one of the first surface and the second surface, and the plurality of positions being separated from each other;
the plurality of first adhesives and a plurality of spacers are arranged at intervals when the first surface and the second surface are brought together; and
an amount of a corresponding one first adhesive of the plurality of first adhesives arranged at each of the plurality of position on the at least one of the first surface and the second surface is greater than or equal to an amount of a corresponding one second adhesive of the plurality of second adhesives arranged at each of the plurality of positions on the at least one of the first surface and the second surface in step S12.

7. The chip packaging method according to claim 1, wherein in the step S2 of arranging the first adhesive, at least part of the first adhesive is arranged on the spacer.

8. The chip packaging method according to claim 2, wherein the step S12 comprises:
curing the second adhesive for a first time; and
detecting whether the cured second adhesive reaches a predetermined height, and in response to that the cured second adhesive fails to reach the predetermined height, replenishing the second adhesive, and performing said curing and said detection again, until the cured second adhesive reaches the predetermined height.

9. The chip packaging method according to claim 1, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

10. The chip packaging method according to claim 2, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

11. The chip packaging method according to claim 3, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

12. The chip packaging method according to claim 4, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

13. The chip packaging method according to claim 5, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

14. The chip packaging method according to claim 6, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

15. The chip packaging method according to claim 7, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

16. The chip packaging method according to claim 8, wherein in the step S4 of curing the first adhesive, the package substrate and the chip are tightly pressed against each other, the first surface and the second surface being kept parallel to each other during tightly pressing the package substrate and the chip against each other, and the spacer being in contact with the first surface and the second surface.

17. A chip packaging structure, comprising:
a package substrate having a first surface;
a chip having a second surface, a void layer being formed between the first surface and the second surface;
a spacer sandwiched between the first surface and the second surface; and
a first adhesive arranged in the void layer, the first surface being adhered to the second surface by the first adhesive, or the first surface being adhered to the second surface through the first adhesive and the spacer, wherein a distribution area of the first adhesive at the second surface is smaller than an area of the second surface.
